(19) United States
(12) Patent Application Publication
(10) Pub. No.: US 2009/0243741 A1
(43) Pub. Date: Oct. 1, 2009

(54) METHOD AND SYSTEM FOR PROCESSING SIGNALS VIA AN OSCILLATOR LOAD EMBEDDED IN AN INTEGRATED CIRCUIT (IC) PACKAGE

(76) Inventor: Ahmadreza Rofougaran, Newport Coast, CA (US)

Correspondence Address: MCANDREWS HELD & MALLOY, LTD, 500 WEST MADISON STREET, SUITE 3400, CHICAGO, IL, 60661, US

(21) Appl. No.: 12/056,505

(22) Filed: Mar. 27, 2008

(51) Int. Cl. H03B 5/08

(52) U.S. Cl. 331/179

(57) ABSTRACT

Aspects of a method and system for processing signals via an oscillator load embedded in an IC package are provided. In this regard, a hybrid circuit may comprise an oscillator, and a frequency of the oscillator may be controlled via a digital control word. Furthermore, the hybrid circuit may comprise an integrated circuit bonded to a multi-layer package and at least a portion of the oscillator may be within and/or on the multi-layer package. The at least a portion of the oscillator may be fabricated in one or more metal layers of the multi-layer package. The at least a portion of the oscillator in the multi-layer package may be fabricated utilizing microstrip and/or stripline transmission line. A frequency of the oscillator may be controlled via one or more inductors and/or capacitors in the portion of the oscillator in the multi-layer package.

### CROSS-REFERENCE TO RELATED APPLICATIONS/INCORPORATION BY REFERENCE

Not applicable.

### FIELD OF THE INVENTION

Certain embodiments of the invention relate to signal processing. More specifically, certain embodiments of the invention relate to a method and system for processing signals via an oscillator load embedded in an integrated circuit (IC) package.

### BACKGROUND OF THE INVENTION

The number and types of wireless devices and wireless standards has seen rapid growth in recent years and is unlikely to slow anytime soon. Consequently, available frequency bands, which are regulated by organizations such as the FCC in the USA, are becoming increasingly scarce. Moreover, existing frequency bands are becoming increasingly congested with wireless traffic from the plethora of users and devices in existence. In this regard, designing devices that can reliably operate in such noisy frequency bands is becoming increasingly difficult and costly. Accordingly, efforts exist to develop wireless technologies which operate at higher, less congested frequencies.

However, as frequencies utilized by various wireless technologies and devices continue to increase, signal generation for the processing, transmission, and/or reception of such signals is becoming increasingly challenging for wireless systems designers. In this regard, conventional methods of signal generation, such as integer-N and Fractional-N phase locked loops may be difficult or costly to implement as frequencies increase. For example, traditional signal generation circuits may require complicated and/or expensive tuning. Additionally, traditional signal generation circuits may require large amounts of circuit area. Accordingly, improved methods and systems for generating signals for the processing, transmission, and/or reception of signals up to extremely high frequencies are needed.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method is provided for processing signals via an oscillator load embedded in an IC package, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram illustrating an exemplary phased locked loop (PLL), in accordance with an embodiment of the invention.

FIG. 2 is a flow chart illustrating exemplary steps for generating a reduced jitter signal, in accordance with an embodiment of the invention.

FIG. 3a is a diagram of an exemplary oscillator, in accordance with an embodiment of the invention.

FIG. 3b is a diagram of an exemplary oscillator, in accordance with an embodiment of the invention.

FIG. 3c is a diagram of an exemplary oscillator, in accordance with an embodiment of the invention.

FIG. 4A illustrates VCO load inductors fabricated on an integrated circuit package, in accordance with an embodiment of the invention.

FIG. 4B illustrates a portion of a VCO tank circuit fabricated in an integrated circuit package, in accordance with an embodiment of the invention.

FIG. 5 is a block diagram illustrating an exemplary RF communication device for processing signals via an oscillator load embedded in an IC package, in accordance with an embodiment of the invention.

### DETAILED DESCRIPTION OF THE INVENTION

Certain embodiments of the invention may be found in a method and system for processing signals via an oscillator load embedded in an IC package. In various embodiments of the invention, a hybrid circuit may comprise an oscillator, and a frequency of the oscillator may be controlled via a digital control word. In this regard, the hybrid circuit may comprise an integrated circuit bonded to a multi-layer package and at least a portion of the oscillator may be within and/or on the multi-layer package. At least a portion of the oscillator may be fabricated in one or more metal layers of the multi-layer package. The at least a portion of the oscillator in the multi-layer package may be fabricated utilizing microstrip and/or stripline transmission line. In various embodiments of the invention, the integrated circuit may be flip chip bonded to the multi-layer package.

In accordance with various embodiments of the invention, a frequency of the oscillator may be controlled via one or more inductors and/or capacitors in the portion of the oscillator in the multi-layer package. A capacitance of the oscillator may be controlled via a digital control word. In this regard, the oscillator may comprise one or more banks of capacitors communicatively coupled via one or more switching elements. A capacitance of the oscillator may be controlled via an analog representation of a portion of the digital control word. In this regard, the oscillator may comprise one or more voltage controlled capacitors.

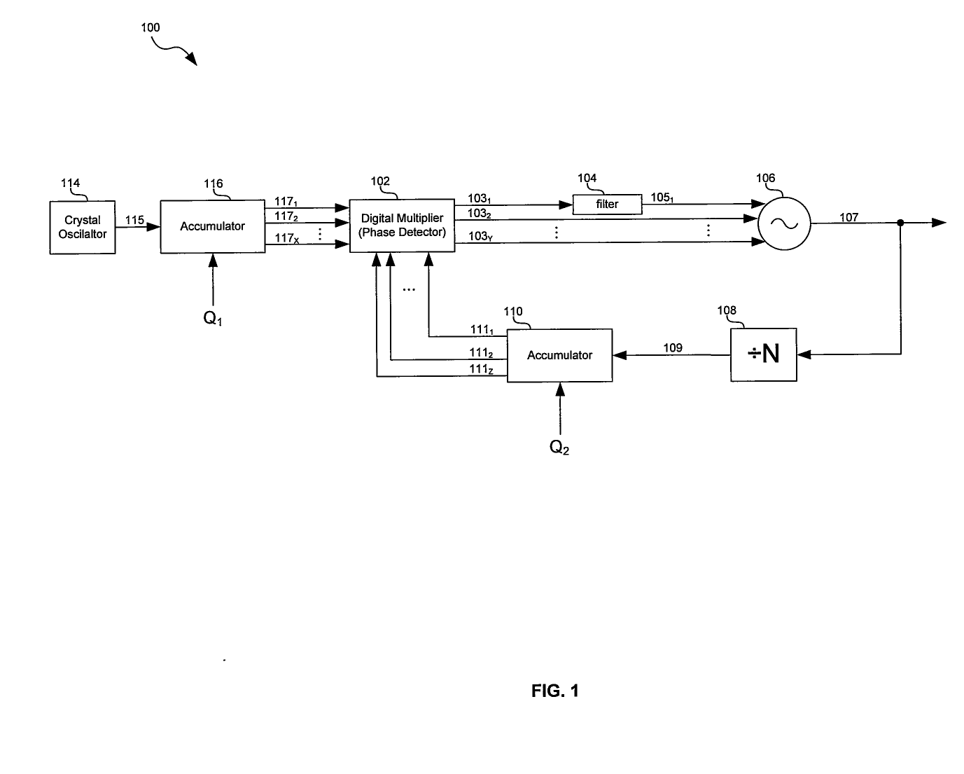

FIG. 1 is a block diagram illustrating an exemplary PLL with a oscillator, in accordance with an embodiment of the invention. Referring to FIG. 1 an exemplary PLL may comprise a crystal oscillator 114, an analog-to-digital converter (A/D) 116, a digital multiplier 102, a filter 104, an oscillator 106, a frequency divider 108, and an accumulator 110.

The crystal oscillator 114 may comprise suitable logic, circuitry, and/or code that may enable generating a stable reference frequency. The oscillator 114 may be enabled to generate signals that may be utilized to clock, for example, the accumulator 110.

The accumulator 116 may comprise suitable logic, circuitry, and/or code that may enable successively adding a control word Q1 to a value stored in the accumulator on each cycle of a reference clock. The accumulator 116 may receive the control word Q₁ and a reference signal. In this regard, the control word Q₁ and the reference signal may determine a phase and/or a frequency of the output signal 117. In an exemplary embodiment of the invention, the accumulator 116 may be clocked by the crystal oscillator 114. The control word Q₁ may be successively added to a value stored in the accumulator 116 on each cycle of the signal 115. In this manner, the sum resulting from the addition of Q1 to the value stored in the accumulator may eventually be greater than the maximum value the accumulator may store, and the value in the accumulator may overflow or “wrap”. Accordingly, an n-bit accumulator may overflow at a frequency f₀ given by EQ. 1.

f₁₁₆=f₁₁₅(Q₁/2ₙ) EQ. 1

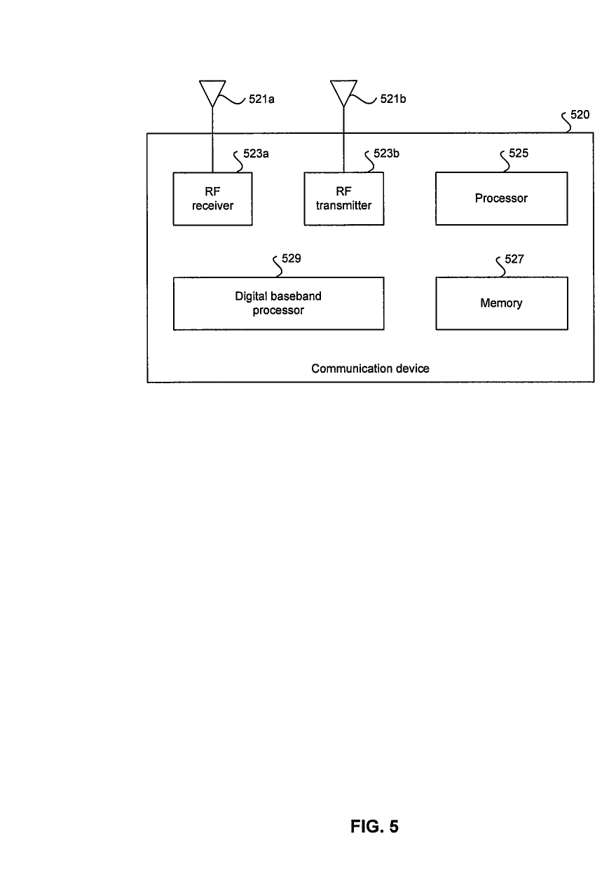

In this manner, the output of the accumulator 116 may be periodic with period 1/f₁₁₆. Additionally, the control word, Q₁, may be provided by, for example, the processor 525 of FIG. 5. In this regard, possible values of the control word may be generated based on possible values of the reference frequency 115 and the desired frequency of the signal 107. Values of the control word Q₂ may be stored in, for example, a look up table in the memory 527 of FIG. 5.

The digital multiplier 102 may comprise suitable logic, circuitry, and/or code that may enable multiplication of the digital signals 111 and 117 and outputting the product via 103₁, . . . , 103_{y}. An average value of the product of the signals 111 and 117 may be utilized to determine a phase difference between the signals 111 and 117. In this regard, an average product of 0 may indicate the signals 111 and 117 are in-phase, while a non-zero average product may indicate a phase difference between the signals 111 and 117. Accordingly, in instances that the average product of the signals 111 and 117 is not 0, then the signal 103 may be adjusted and when the average product is 0, then the signal 103 may stabilize. However, due to the resolution of the digital multiplier, an exact phase lock may lie in between two successive values of the control word 103 which may result in the LSB 103₁ toggling between high and low. Thus, controlling the oscillator 106 with 103₁ may result in jitter on the output signal 107.

The filter 104 may comprise suitable logic, circuitry and/or code that may enable filtering the least significant bit 103₁ output by the multiplier 102. In an exemplary embodiment of the invention, the signal 105₁ output by the filter 104 may correspond to an average value of the signal 103₁. In this manner, jitter and/or noise in the signal 103₁, and thus in the output signal 107, may be reduced. For example, the filter 104 may integrate the signal 103₁ and the signal 105₁ may be a voltage which may correspond to an average voltage of the signal 103₁.

The oscillator 106 may comprise suitable logic, circuitry, and/or code that may enable generating a signal 107 based on signals 103 and 105. In this regard, the frequency of the signal 107 may be determined, at least in part, by the digital control word 103 and analog signal 105. In an exemplary embodiment of the invention, the digital signal 103 may enable a quick and/or course frequency control and the analog signal 105 may enable a fine frequency control.

The frequency divider 108 may comprise suitable logic, circuitry, and/or code for receiving a first, higher frequency and outputting a second, lower frequency. The scaling factor, N, may be determined based on one or more control signals from, for example, the processor 525 of FIG. 5. In this regard, values for the frequency divider 108 may be stored in, for example, a look-up table in the memory 527 of FIG. 5.

The accumulator 110 may comprise suitable logic, circuitry, and/or code that may enable successively adding a digital control word Q₂ to a value stored in the accumulator 110 on each cycle of a reference clock. The accumulator 110 may receive the control word Q₂ and a reference signal. In this regard, the control word Q₂ and the reference signal may determine a phase and/or a frequency of the output signal 111. In an exemplary embodiment of the invention, the accumulator 110 may be clocked by the VCO output 107, or, as depicted in FIG. 1, the signal 109 which may be a divided down version of the VCO output 107. The control word Q may be successively added to a value stored in the accumulator on each cycle of the reference clock. In this manner, the sum may eventually be greater than the maximum value the accumulator 110 may store, and the value in the accumulator may overflow or “wrap”. Accordingly, an N-bit accumulator will overflow at a frequency f₀ given by EQ. 2.

f₁₁₀=f₁₀₉(Q₂/2ⁿ) EQ. 2

In this manner, the output of the accumulator 110 may be periodic with period 1/f₁₁₀. Additionally, the control word, Q₂, may be provided by, for example, the processor 525 of FIG. 5. In this regard, possible values of the control word may be stored in, for example, a look up table in the memory 527 of FIG. 5.

In operation the PLL 100 may generate a signal 107 based on the fixed frequency reference signal 115 from the crystal oscillator 114. In this regard, the accumulator 110 may enable generating, based on the signal 109 and the control word Q, a digital signal 111. The signal 111 may provide feedback such that the oscillator 106 may generate a signal of varying frequency while having the stability of the fixed frequency crystal oscillator 114. In this regard, the multiplier 102 may compare the phase of the signal 117 to the phase of the signal 111 and generate an error signal 103 indicative of the phase difference between the signals 111 and 117. The error signal 103 may be a digital signal comprising one or more bits. The least significant bit 103₁ may be filtered, integrated, or otherwise processed so as to obtain the signal 105, which may correspond to the average value of the signal 103₁. The signals 103₂, . . . , 103_{N} and 105₁ may control a capacitance, and thus a frequency, of the oscillator 107. In this manner, the phase error between the signal 111 and the signal 117 may be maintained within determined limits. Accordingly, the output signal 107 of the oscillator 106 may be any integer multiple or fractional multiple of the reference signal 115. In this regard, the signal 111 may be determined using

$${f}_{111} = \frac{{f}_{107}}{N} \cdot {Q}_{2} \cdot \frac{1}{{2}^{n}} \qquad EQ . 3$$

where f₁₁₁ is the frequency of the signal 111, f₁₀₇ is the frequency of the signal 107, N is the divide ratio of the frequency divider 108, Q₂ is the value of the control word input to the accumulator 110, and ‘n’ is the number of bits of the accumulator 110. Accordingly, the PLL 100 may be enabled to generate a wide range of frequencies, with high resolution, without the need of a traditional fractional-N synthesizer.

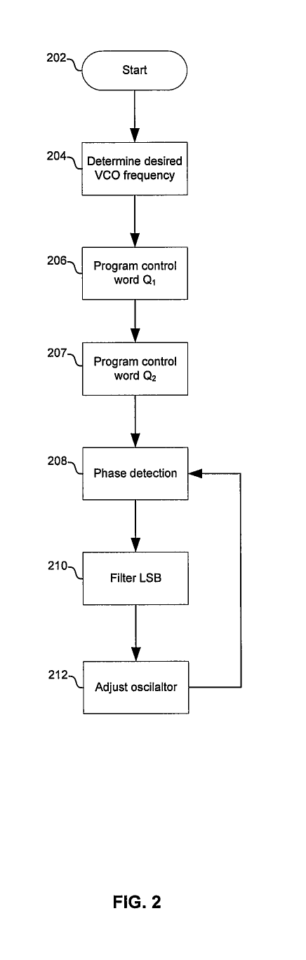

FIG. 2 is a flow chart illustrating exemplary steps for generating a reduced jitter signal, in accordance with an embodiment of the invention. Referring to FIG. 2, the exemplary steps may begin with start step 202. Subsequent to start step 202, the exemplary steps may advance to step 204. In step 204, a desired frequency to be output by the oscillator 106 may be determined. In this regard, in instances that the PLL 100 may be utilized to transmit or receive RF signals, then the output of the oscillator 106 may be determined based on the RF transmit and/or RF receive frequency. Subsequent to step 204, the exemplary steps may advance to step 206. In step 206, the digital control word Q₁ input to the accumulator 116 may be determined. In this regard, the value of the digital control word Q₁ may be determined based on a desired reference frequency of the signal 117. Subsequent to step 206, the exemplary steps may advance to step 207. In step 207, the digital control word Q₂ input to the accumulator 110 may be determined. In this regard, the value of the digital control word Q₂ may be determined utilizing EQ. 3 above. Accordingly, for different values of the reference frequency 115 and/or the desired output frequency 107, the value of the digital control word may be adjusted. In this regard, a processor, such as the processor 525 or the processor 529 of FIG. 5, may be enabled to programmatically control the value of the digital control word.

Subsequent to step 206, the exemplary steps may advance to step 208. In step 208, a phase difference between the signal 111 and the signal 117 may be determined. The phase difference may be determined by multiplying the signals 111 and 117. In this regard, the average value of the product of the signals 111 and 117 may be indicative of a phase difference between the signals 111 and 117. Subsequent to step 208, the exemplary steps may advance to step 210. In step 210, the least significant bit of the digital control word 103, may be filtered to generate the signal 105₁. In this manner, 105₁ may correspond to the average value of the signal 103₁. Subsequent to step 210, the exemplary steps may advance to step 212. In step 212, the oscillator 106 may be adjusted based on the phase difference between the signals 111 and 117. For example, a capacitance coupled to an output node of the oscillator 106 may be adjusted such that the phase difference between the signals 111 and 117 may be reduced. In this regard, the capacitance may comprise a bank of capacitors, controlled via the signals 103₂, . . . , 103_{N}, and one or more voltage controlled varactors, controlled via the signal 105₁. Accordingly, in instances when there may be no phase difference between the signals 111 and 117 the signals 103 and 105 may stabilize and the PLL may be “locked”. Subsequent to step 210, the exemplary steps may return to step 208. In this regard, maintaining phase lock may be a continuous process that may require periodic or even constant feedback.

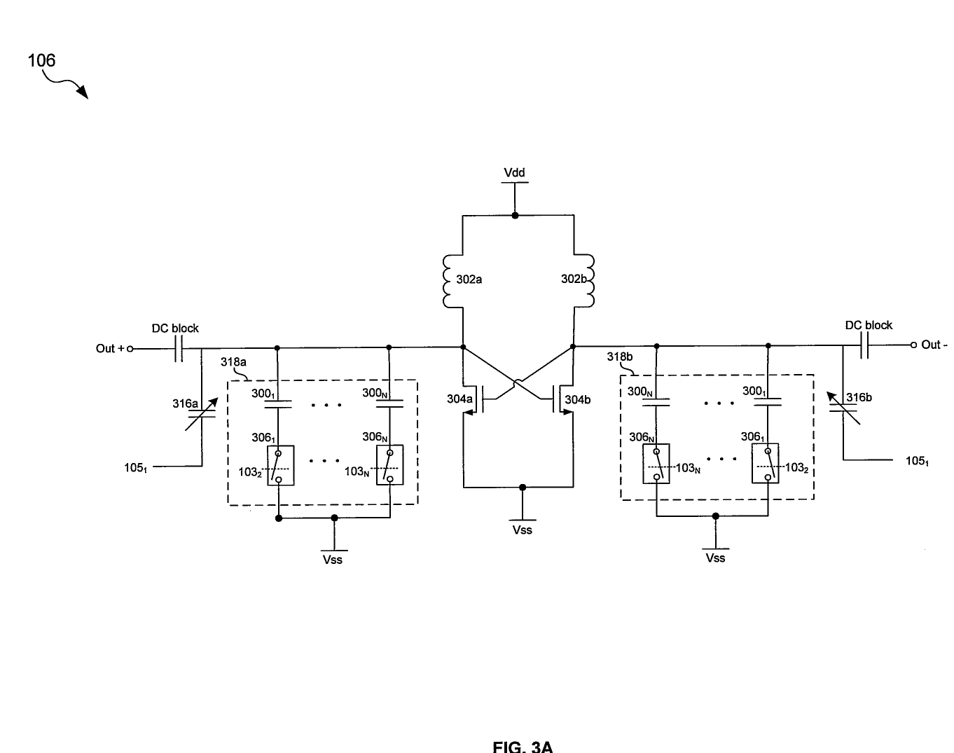

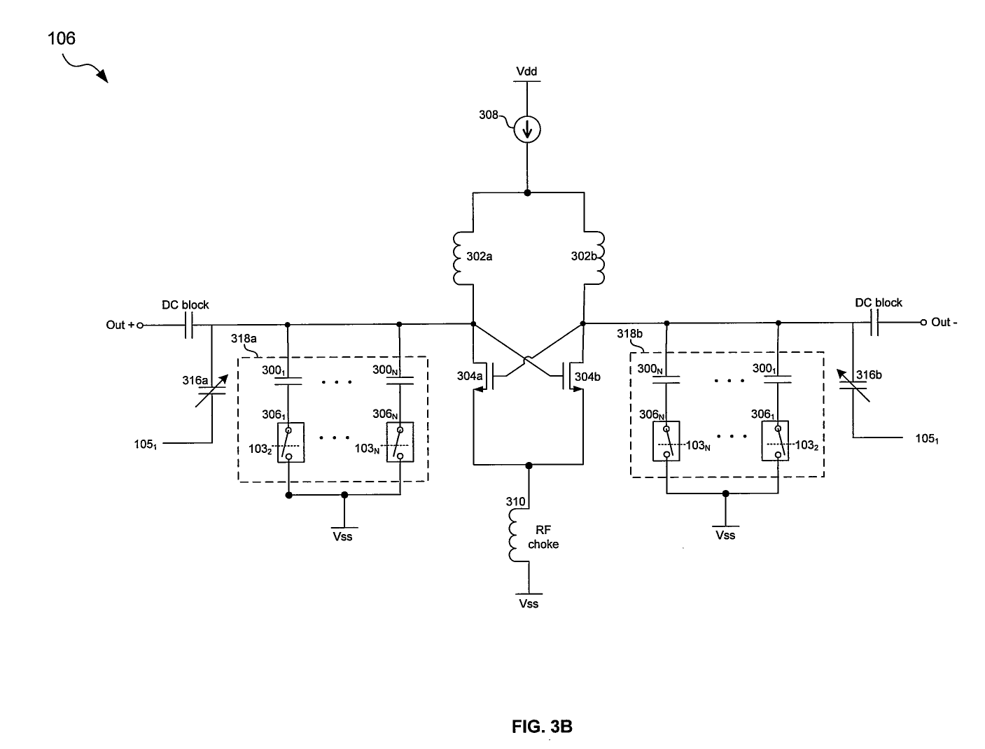

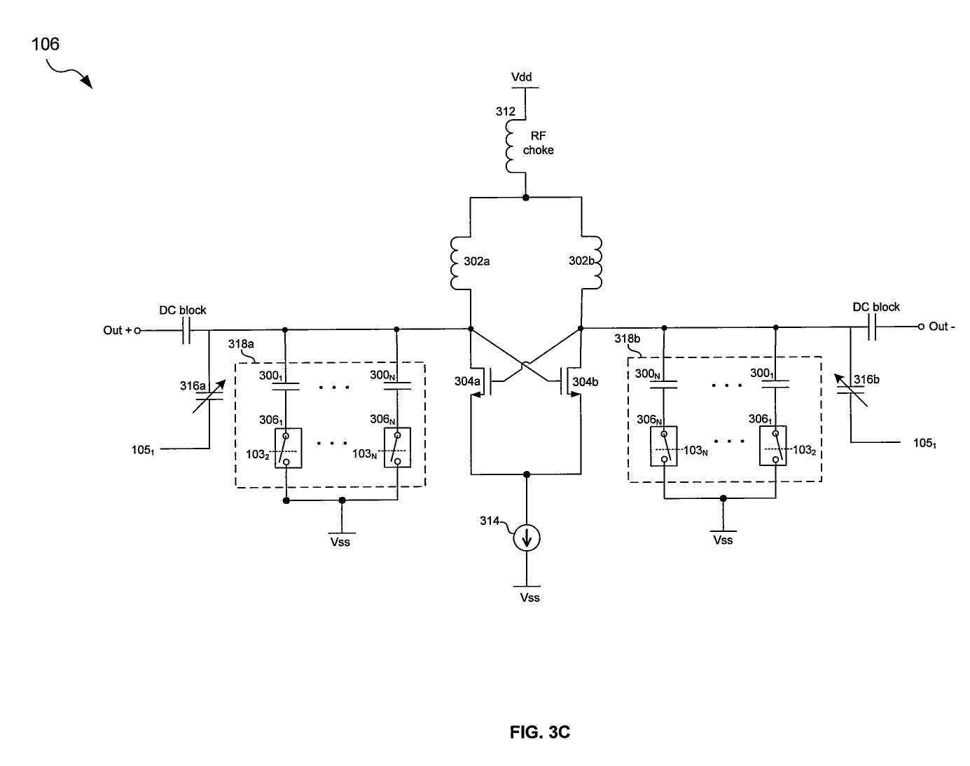

FIG. 3a is a diagram of an exemplary oscillator, in accordance with an embodiment of the invention. Referring to FIG. 3a there is shown an exemplary oscillator 106 which may comprise capacitor banks 318, varactors 316, a pair of transistors 304, and a pair of inductors 302. The capacitor banks 318 may comprise one or more capacitances 300 and one or more switching elements 306.

In various embodiments of the invention, the varactors 316 may comprise diodes for which a junction capacitance determined by a reverse bias voltage applied to the diodes.

In various embodiments of the invention, the signal 103 described with respect to FIG. 1 may comprise N bits, where N may be an integer greater than 0. Accordingly, the capacitor banks 318 may be controlled via the N−1 most significant bits of the digital control word 103 and the varactors 316 may be controlled via the signal 105₁, which may correspond to an average voltage of the least significant bit of the digital control word 103.

In operation, the switching elements 306 may enable coupling and decoupling of the capacitors 300 to the output nodes “out+” and/or “out−”. Accordingly, depending on the value of the digital signal(s) 103₂, . . . , 103_{N}, one or more capacitances 300 may be coupled or decoupled from the output nodes and may thus alter the frequency of oscillation of the outputs. In various embodiments of the invention, the signal 103 may be delta sigma modulated and thus an effective capacitance of the capacitor banks 318 at the output nodes may depend on factors such as switching frequency and duty cycle of the signal 103.

FIG. 3b is a diagram of an exemplary oscillator, in accordance with an embodiment of the invention. In this regard, FIG. 3b depicts an alternative to the embodiment illustrated in FIG. 3a. Referring to FIG. 3b there is shown an exemplary oscillator 106 which may comprise capacitor banks 318, varactors 316, a pair of transistors 304, a pair of inductors 302, a current source 308, and an RF choke 310.

The capacitors banks 318, varactors 316, transistors 304, and inductors 302 may be as described in FIG. 3a. The current source 308 may comprise suitable logic, circuitry, and/or code for supplying a constant (within a tolerance) current. The RF choke 310 may enable sinking DC current to GND while impeding AC current. The oscillator of FIG. 3b may enable alternative biasing arrangements as compared to the oscillator of FIG. 3a. Accordingly, choosing one embodiment or the other may provide flexibility when designing the PLL 100.

FIG. 3c is a diagram of an exemplary oscillator, in accordance with an embodiment of the invention. In this regard, FIG. 3c depicts an alternative to the embodiments illustrated in FIG. 3a and 3b. Referring to FIG. 3b there is shown an exemplary oscillator 106 which may comprise capacitor banks 318, varactors 316, a pair of transistors 304, a pair of inductors 302, a current source 308, and an RF choke 310.

The capacitors banks 318, varactors 316, transistors 304, and inductors 302 may be as described in FIG. 3a. The RF choke 312 may enable passing DC current from VDD while impeding AC current. The current source 314 may comprise suitable logic, circuitry, and/or code for sinking a constant (within determined limits) current. The oscillator of FIG. 3c may enable alternative biasing arrangements as compared to the oscillators of FIG. 3a and FIG. 3b. Accordingly, choosing between the various embodiments may provide flexibility when designing the PLL 100.

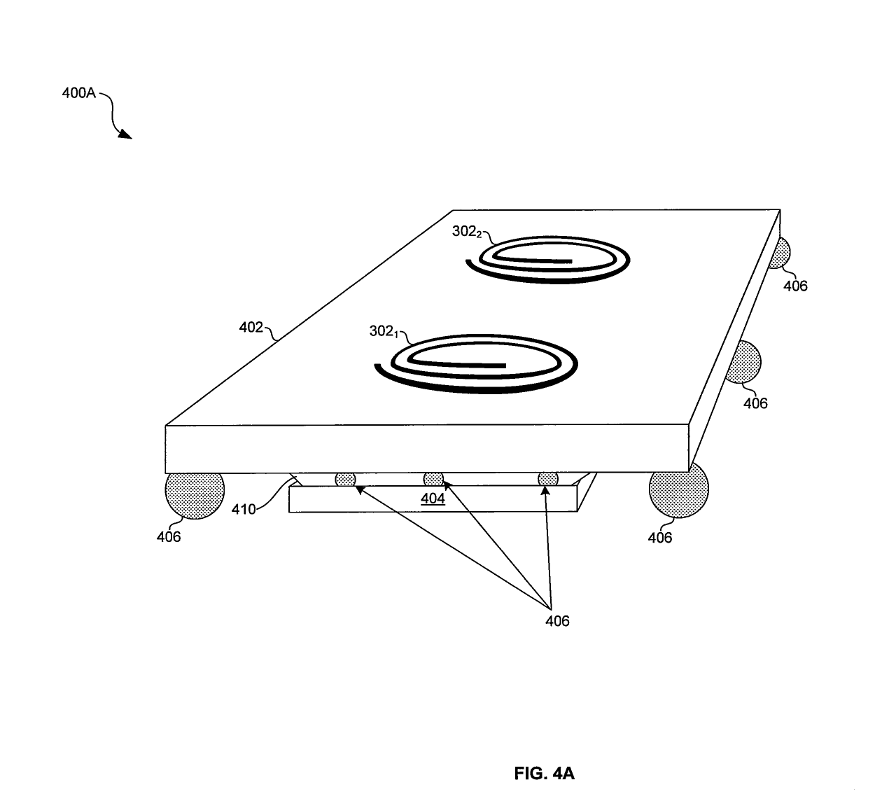

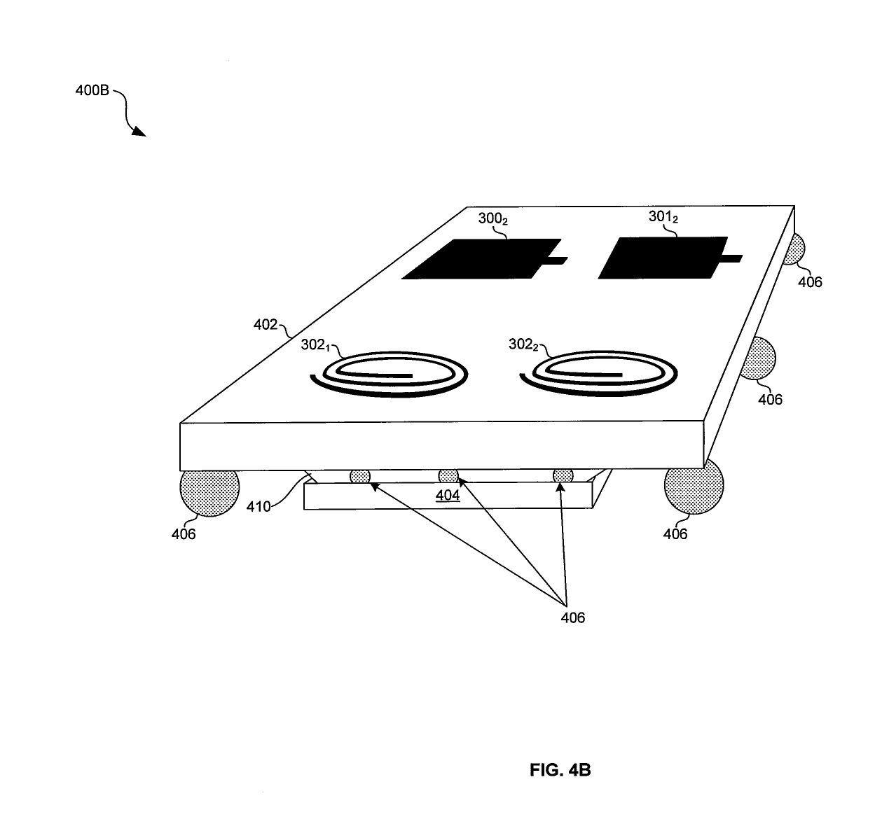

FIG. 4A illustrates VCO load inductors fabricated on an integrated circuit package, in accordance with an embodiment of the invention. Referring to FIG. 4A, the system 400A may comprise an Integrated circuit (IC) package 402, an associated IC (“chip”) 404, inductors 302₁ and 302₂, thermal epoxy 410, and solder balls 406. In this regard, the system 400A may, for example, be referred to as a hybrid, a hybrid circuit, or a hybridized circuit.

The IC 404 may comprise logic, circuitry, and/or code for signal processing. In this regard, the IC 104 may comprise a PLL similar to or the same as the PLL 100 described with respect to FIG. 1. The IC 404 may be bump-bonded or flip-chip bonded to the multi-layer IC package 402 utilizing the solder balls 406. In this manner, wire bonds connecting the IC 404 to the multi-layer IC package 402 may be eliminated, reducing and/or eliminating stray inductances due to wire bonds. In addition, the thermal conductance out of the IC 404 may be greatly improved utilizing the solder balls 406 and the thermal epoxy 410. The thermal epoxy 410 may be electrically insulating but thermally conductive to allow for thermal energy to be conducted out of the IC 404 to the much larger thermal mass of the multilayer package 402.

The solder balls 406 may comprise spherical balls of metal to provide electrical, thermal and physical contact between the IC 404 and the multi-layer IC package 402. In making the contact with the solder balls 406, the IC 404 may be pressed with enough force to squash the metal spheres somewhat, and may be performed at an elevated temperature to provide suitable electrical resistance and physical bond strength. The solder balls 406 may also be utilized to provide electrical, thermal and physical contact between the multi-layer IC package 402 and a printed circuit board (not shown).

The multi-layer IC package 402 may comprise one or more layers of metal and/or insulating material (various embodiments may also comprise ferromagnetic and/or ferrimagnetic areas and/or layers). In this regard, the package 402 may be fabricated in a manner similar to or the same as an integrated circuit. Accordingly, the layers may be utilized to realize circuit elements such as resistors, inductors, capacitors, transmission lines, switches (e.g., micro-electro-mechanical switches), and antennas. In this regard, the inductors 302₁ and 302₂ may be fabricated in and/or on the package 402. The inductors 302₁ and 302₂ may be similar to or the same as described with respect to FIGS. 3A, 3B, and 3C. The inductors 302₁ and 302₂ may be fabricated in one or more metal layers in and/or on the package 402. In this regard, microstrip and/or stripline may be utilized to delineate the inductors 302₁ and 302₂.

The inductors 302₁ and 302₂ may be part of an oscillator circuit a, such as the oscillator 106. In this regard, inductors on and/or in the package 402 may be larger and/or cheaper than inductors fabricated in the chip 404. Moreover, a quality factor of inductors on and/or in the package 402 may be higher than inductors realized on the chip 404. Accordingly, the frequency of the VCO may be more accurate than when on-chip inductors are utilized.

FIG. 4B illustrates a portion of a VCO tank circuit fabricated in an integrated circuit package, in accordance with an embodiment of the invention. Referring to FIG. 4B, the system 400B may be similar to the system 400A but may additionally comprise one or more capacitors fabricated in and/or on the package 402. In an exemplary embodiment of the invention, the capacitors 300₂ and 301₂ may reside in and/or in the package 402. In this regard, the capacitors 300₂ and 301₂ may establish an initial VCO frequency near a desired frequency. Switching the capacitors 300₃, . . . , 300_{N} and 301₃, . . . , 301_{N} in and/or out of the VCO circuit 106 may provide a coarse tuning to adjust the VCO 106 closer to the desired frequency. The varactors 300ᵢ and 301₁ may provide a fine tuning to adjust the VCO 106 to precisely the desired frequency (within a tolerance).

In various other embodiments of the invention, additional and/or different inductors may be embedded in the package 402. For example, the banks of capacitors 318a and/or 318b may be fabricated in one or more metal layers of the package 104.

FIG. 5 is a block diagram illustrating an exemplary RF communication device for processing signals via an oscillator load embedded in an IC package, in accordance with an embodiment of the invention. Referring to FIG. 5, there is shown a RF communication device 520 that may comprise an RF receiver 523a, an RF transmitter 523b, a digital baseband processor 529, a processor 525, and a memory 527. A receive antenna 521a may be communicatively coupled to the RF receiver 523a. A transmit antenna 521b may be communicatively coupled to the RF transmitter 523b. The RF communication device 520 may be operated in a system, such as the cellular network and/or digital video broadcast network, for example.

The RF receiver 523a may comprise suitable logic, circuitry, and/or code that may enable processing of received RF signals. The receiver may be enabled to generate signals, such as local oscillator signals, for the reception and processing of RF signals. In this regard, the RF receiver 523a may comprise an oscillator such as the oscillator 106 for generating local oscillator signals. For example, the RF receiver 523a may be in an IC such as the IC 404 and a portion of the oscillator load may be embedded in the package 402. Accordingly, the RF receiver 523a may down-convert received RF signals to a baseband frequency signal utilizing one or more local oscillator signals generated via an oscillator with load embedded in an IC package. The RF receiver 523a may perform direct down-conversion of the received RF signal to a baseband frequency signal, for example. In some instances, the RF receiver 523a may enable analog-to-digital conversion of the baseband signal components before transferring the components to the digital baseband processor 529. In other instances, the RF receiver 523a may transfer the baseband signal components in analog form.

The digital baseband processor 529 may comprise suitable logic, circuitry, and/or code that may enable processing and/or handling of baseband frequency signals. In this regard, the digital baseband processor 529 may process or handle signals received from the RF receiver 523a and/or signals to be transferred to the RF transmitter 523b. The digital baseband processor 529 may also provide control and/or feedback information to the RF receiver 523a and to the RF transmitter 523b based on information from the processed signals. In this regard, the baseband processor 529 may provide one or more control signals to, for example, the accumulator 114, the multiplier 102, the filter 104, the oscillator 106, the frequency divider 108, and/or the accumulator 110. The digital baseband processor 529 may communicate information and/or data from the processed signals to the processor 525 and/or to the memory 527. Moreover, the digital baseband processor 529 may receive information from the processor 525 and/or to the memory 527, which may be processed and transferred to the RF transmitter 523b for transmission to the network.

The RF transmitter 523b may comprise suitable logic, circuitry, and/or code that may enable processing of RF signals for transmission. The transmitter may be enabled to generate signals, such as local oscillator signals, for the transmission and processing of RF signals. In this regard, the RF transmitter 523b may comprise an oscillator such as the oscillator 106 for generating local oscillator signals. For example, the RF transmitter 523b may be in an IC such as the IC 404 and a portion of the oscillator load may be embedded in the package 402. Accordingly, the RF transmitter 523b may up-convert the baseband frequency signal to an RF signal utilizing one or more local oscillator signals generated via an oscillator with load embedded in an IC package. The RF transmitter 523b may perform direct up-conversion of the baseband frequency signal to a RF signal, for example. In some instances, the RF transmitter 523b may enable digital-to-analog conversion of the baseband signal components received from the digital baseband processor 529 before up conversion. In other instances, the RF transmitter 523b may receive baseband signal components in analog form.

The processor 525 may comprise suitable logic, circuitry, and/or code that may enable control and/or data processing operations for the RF communication device 520. The processor 525 may be utilized to control at least a portion of the RF receiver 523a, the RF transmitter 523b, the digital baseband processor 529, and/or the memory 527. In this regard, the processor 525 may generate at least one signal for controlling operations within the RF communication device 520. In this regard, the baseband processor 529 may provide one or more control signals to, for example, the accumulator 114, the multiplier 102, the filter 104, the oscillator 106, the frequency divider 108, and/or the accumulator 110. The processor 525 may also enable executing of applications that may be utilized by the RF communication device 520. For example, the processor 525 may execute applications that may enable displaying and/or interacting with content received via RF signals in the RF communication device 520.

The memory 527 may comprise suitable logic, circuitry, and/or code that may enable storage of data and/or other information utilized by the RF communication device 520. For example, the memory 527 may be utilized for storing processed data generated by the digital baseband processor 529 and/or the processor 525. The memory 527 may also be utilized to store information, such as configuration information, that may be utilized to control the operation of at least one block in the RF communication device 520. For example, the memory 527 may comprise information necessary to configure the RF receiver 523a to enable receiving signals in the appropriate frequency band. In this regard, the memory 527 may store configuration and/or control information for the accumulator 114, the multiplier 102, the filter 104, the oscillator 106, the frequency divider 108, and/or the accumulator 110.

Certain embodiments of the invention may be found in a method and system for processing signals via an oscillator load embedded in an IC package. In various embodiments of the invention, a hybrid circuit 400A and/or 400B may comprise an oscillator 106 and a frequency of the oscillator 106 may be controlled via a digital control word 103. In this regard, the hybrid circuit 400A and/or 400B may comprise an integrated circuit 404 bonded to a multi-layer package 402 and at least a portion of the oscillator 106 may be within and/or on the multi-layer package 402. In this regard, at least a portion of the oscillator 106 may be fabricated in one or more metal layers of the multi-layer package. The at least a portion of the oscillator 106 in the multi-layer package 402 may be fabricated utilizing microstrip and/or stripline transmission line. In various embodiments of the invention, the integrated circuit 404 may be flip chip bonded to the multi-layer package.

In accordance with various embodiments of the invention, a frequency of the oscillator 106 may be controlled via one or more inductors 302 and/or capacitors 300 in the portion of the oscillator 106 in the multi-layer package 402. A capacitance of the oscillator 106 may be controlled via the digital control word 103. In this regard, the oscillator 106 may comprise one or more banks of capacitors 318 communicatively coupled via one or more switching elements 103. A capacitance of the oscillator 106 may be controlled via an analog representation 105₁ of a portion of the digital control word 103. In this regard, the oscillator may comprise one or more voltage controlled capacitors 316.

Another embodiment of the invention may provide a machine-readable storage, having stored thereon, a computer program having at least one code section executable by a machine, thereby causing the machine to perform the steps as described herein for processing signals via an oscillator load embedded in an IC package.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for signal processing, the method comprising:
in a hybrid circuit comprising an integrated circuit bonded to a multi-layer package, controlling a frequency of an oscillator via a digital control word, wherein at least a portion of said oscillator is within and/or on said multi-layer package.

2. The method according to claim 1, wherein said at least a portion of said oscillator is fabricated in one or more metal layers of said multi-layer package.

3. The method according to claim 1, wherein said at least a portion of said oscillator is fabricated in microstrip transmission line.

4. The method according to claim 1, wherein said at least a portion of said oscillator is fabricated in stripline transmission line.

5. The method according to claim 1, comprising controlling a frequency of said oscillator via an inductance of one or more inductors in said at least a portion of said oscillator

6. The method according to claim 1, comprising controlling a frequency of said oscillator via a capacitance of one or more capacitors in said at least a portion of said oscillator.

7. The method according to claim 1, comprising controlling a capacitance in said oscillator via a portion of said digital control word.

8. The method according to claim 7, wherein said capacitance comprises a bank of capacitors communicatively coupled via one or more switching elements.

9. The method according to claim 1, comprising controlling a capacitance in said oscillator via an analog representation of a portion of said digital control word.

10. The method according to claim 9, wherein said capacitance comprises a voltage controlled capacitor.

11. The method according to claim 1, wherein said integrated circuit is flip-chip bonded to said multi-layer package.

12. A system for signal processing, the system comprising:
one or more circuits in a hybrid circuit, said hybrid circuit comprising an integrated circuit bonded to a multi-layer package and said one or more circuits comprising an oscillator, wherein said one or more circuits enable control of a frequency of said oscillator via a digital control word, wherein at least a portion of said oscillator is within and/or on said multi-layer package.

13. The system according to claim 12, wherein said at least a portion of said oscillator is fabricated in one or more metal layers of said multi-layer package.

14. The system according to claim 12, wherein said at least a portion of said oscillator is fabricated in microstrip transmission line.

15. The system according to claim 12, wherein said at least a portion of said oscillator is fabricated in stripline transmission line.

16. The system according to claim 12, wherein said at least a portion of said oscillator comprises one or more inductors that, at least in part, determine a frequency of said oscillator.

17. The system according to claim 12, wherein said at least a portion of said oscillator comprises one or more capacitors that, at least in part, determine a frequency of said oscillator.

18. The system according to claim 12, wherein said one or more circuits control a capacitance in said oscillator via a portion of said digital control word.

19. The system according to claim 18, wherein said capacitance comprises a bank of capacitors communicatively coupled via one or more switching elements.

20. The system according to claim 12, wherein said one or more circuits control a capacitance in said oscillator via an analog representation of a portion of said digital control word.

21. The system according to claim 20, wherein said capacitance comprises a voltage controlled capacitor.

22. The system according to claim 12, wherein said integrated circuit is flip-chip bonded to said multi-layer package.
